(19) United States
(12) Patent Application Publication
(10) Pub. No.: US 2015/0125599 A1
(43) Pub. Date: May 7, 2015

(54) POWDER PARTICLE COATING USING ATOMIC LAYER DEPOSITION CARTRIDGE

(71) Applicants: Sven Lindfors, Espoo (FI); Pekka J Soininen, Espoo (FI)

(72) Inventors: Sven Lindfors, Espoo (FI); Pekka J Soininen, Espoo (FI)

(73) Assignee: Picocun Oy, Espoo (FI)

(21) Appl. No.: 14/400,826

(22) PCT Filed: May 14, 2012
(86) PCT No.: PCT/FI2012/050462

§ 371 Date: Dec. 23, 2014

(51) Int. Cl. C23C 16/455; C23C 16/44; C23C 16/442

(52) U.S. Cl. CPC C23C 16/45544; C23C 16/442; C23C 16/45555; C23C 16/4412
USPC 427/213; 118/716

(57) ABSTRACT

A method includes receiving an atomic layer deposition (ALD) cartridge into a receiver of an ALD reactor by a quick coupling method. The ALD cartridge serves as an ALD reaction chamber, and the method includes processing surfaces of particulate material within the ALD cartridge by sequential self-saturating surface reactions.

### FIELD OF THE INVENTION

The present invention generally relates to deposition reactors. More particularly, but not exclusively, the invention relates to such deposition reactors in which material is deposited on surfaces by sequential self-saturating surface reactions.

### BACKGROUND OF THE INVENTION

Atomic Layer Epitaxy (ALE) method was invented by Dr. Tuomo Suntola in the early 1970's. Another generic name for the method is Atomic Layer Deposition (ALD) and it is nowadays used instead of ALE. ALD is a special chemical deposition method based on the sequential introduction of at least two reactive precursor species to at least one substrate.

Thin films grown by ALD are dense, pinhole free and have uniform thickness. For example, in an experiment aluminum oxide has been grown by thermal ALD from trimethylaluminum (CH₃)₃Al, also referred to as TMA, and water at 250-300° C. resulting in only about 1% non-uniformity over a substrate wafer.

One interesting application of ALD technique is coating of small particles. It may be desirable, for example, to deposit a thin coating on particles to alter the surface properties of these particles while maintaining their bulk properties.

### SUMMARY

According to a first example aspect of the invention there is provided a method comprising:

receiving an atomic layer deposition (ALD) cartridge into a receiver of an ALD reactor by a quick coupling method, said ALD cartridge configured to serve as an ALD reaction chamber; and
processing surfaces of particulate material within said ALD cartridge by sequential self-saturating surface reactions.

In certain example embodiments, a bottom-to-top flow causes the particulate material particles to whirl forming fluidized bed within the ALD cartridge. In certain other embodiments, fluidized bed is not formed depending on certain factors, such as the flow rate and the weight of the particles. The particulate material may be powder or more coarse material, such as diamonds or similar.

The receiver may be arranged in an ALD reactor body so that the ALD cartridge is received into the ALD reactor body. The ALD body may form the receiver. The receiver may form part of the ALD reactor body (it may be its integral part) or it may be a fixed receiver integrated to the ALD reactor body, or to an ALD reactor or processing chamber structure. In case of an integrated receiver, the receiver may be integrated into an ALD processing chamber lid.

In certain example embodiments, the quick coupling method comprises twisting the ALD cartridge until a locking member locks the ALD cartridge into its correct place. In certain example embodiments, the quick coupling method comprises using form locking that locks the ALD cartridge into its correct place. In certain example embodiments, the quick coupling method is a combination of these methods.

In certain example embodiments, the method comprises: feeding vibrating gas into the ALD cartridge to hinder the formation of agglomerates within said particulate material.

Vibrating gas may be fed during ALD processing. The vibrating gas may be fed during both precursor exposure periods and purge periods.

In certain example embodiments, the method comprises: using a flow channel separate from precursor in-feed lines to feed vibrating inactive gas into the ALD cartridge during ALD processing.

In many of the example embodiments, percussion may be used in addition to or instead of the vibrating gas.

In certain example embodiments, the method comprises: conducting reaction residue via at least one outlet conduit into exhaust, said at least one outlet conduit being arranged inside the ALD cartridge body.

Instead of one outlet conduit, there may be two outlet conduits, or more.

In certain example embodiments, the method comprises: loading said particulate material via a loading channel arranged inside the ALD cartridge body.

Instead of a pre-filled ALD cartridge, particulate material to be coated may be loaded into the ALD cartridge via a loading channel. The loading channel may be arranged at the bottom section of the ALD cartridge. Alternatively, the ALD cartridge may be loaded from the top via a loading channel arranged at the top section of the ALD cartridge. Alternatively, in certain example embodiments, the ALD cartridge is loaded by removing a removable lid or cover forming the top section of the ALD cartridge in those embodiments.

In certain example embodiments, the method comprises: processing particulate material in a plurality of compartments arranged on top of each other, each compartment having been separated from an adjacent compartment by a filter plate. The filter plate(s) may be sinter filter(s).

In certain example embodiments, gases are fed into the ALD cartridge from the bottom of the ALD cartridge.

According to a second example aspect of the invention there is provided an atomic layer deposition (ALD) reactor comprising:

a receiver configured to receive and ALD cartridge into the ALD reactor by a quick coupling method, said ALD cartridge configured to serve as an ALD reaction chamber; and
in-feed line(s) configured to feed precursor vapor into said ALD cartridge to process surfaces of particulate material within said ALD cartridge by sequential self-saturating surface reactions.

In certain example embodiments, the receiver is the ALD reactor body itself sized and shaped so as to receive the ALD cartridge by quick coupling. In other embodiments, the receiver is implemented as a certain form or a certain part arranged in the ALD reactor body configured to receive the ALD cartridge.

The quick coupling method causes that (flow) conduits inside the ALD reactor and cartridge bodies are in alignment with each other. For example, the said form or part in the ALD reactor body may be sized and shaped so that the respective conduits arranged in the ALD cartridge and ALD reactor body set in alignment with each other.

In certain example embodiments, said receiver is configured to receive said ALD cartridge by a twisting method in which the ALD cartridge is twisted until a locking member locks the ALD cartridge into its correct place.

In certain example embodiments, said receiver is configured to receive said ALD cartridge by a form locking method locking the ALD cartridge into its correct place.

In certain example embodiments, the ALD comprises a vibration source in a flow channel configured to feed vibrating gas into the ALD cartridge to hinder the formation of agglomerates within said particulate material. The vibrating gas may be inactive gas.

In certain example embodiments, the ALD reactor comprises: an outlet conduit inside the ALD reactor body configured to receive reaction residue from an outlet conduit arranged inside the ALD cartridge body.

In certain example embodiments, the ALD reactor comprises: a loading channel inside the ALD reactor body configured to conduct particulate material into a loading channel arranged inside the ALD cartridge body.

In certain example embodiments, the ALD reactor comprises or is configured to form a gas spreading space (or volume) before (i.e., upstream) an inlet filter of the ALD cartridge. The gas spreading space may be below the inlet filter. The gas spreading space may be next to the inlet filter.

In certain example embodiments, the ALD reactor comprises a microfilter tube in the end of a precursor vapor in-feed line. In certain example embodiments, the gas spreading space is arranged around the microfilter tube.

According to a third example aspect of the invention there is provided a removable atomic layer deposition (ALD) cartridge configured to serve as an ALD reaction chamber and comprising a quick coupling mechanism configured to attach to an ALD reactor body of an ALD reactor by a quick coupling method, the ALD cartridge being configured to process surfaces of particulate material within said ALD cartridge by sequential self-saturating surface reactions once attached to the ALD reactor body by the quick coupling method.

In certain example embodiments, the removable ALD cartridge comprises:

an outlet conduit inside the ALD cartridge body configured to conduct reaction residue via the ALD reactor body into exhaust.

In certain example embodiments, the removable ALD cartridge is a cylindrical cartridge. Accordingly, the basic shape of the removable ALD cartridge in certain example embodiments is a cylindrical form. In certain example embodiments, the removable ALD cartridge is a conical cartridge. Accordingly, the basic shape of the removable ALD cartridge in certain example embodiments is a conical form. In certain example embodiments, the removable has both cylindrical part and a conical part. The conical part may be at the bottom.

The ALD cartridge may be downwards tapering. Alternatively, the ALD cartridge may be of uniform width.

In certain example embodiments, the removable ALD cartridge comprises or is configured to receive a plurality of filter plates on top of each other to form a plurality of particulate material coating compartments therebetween. In certain example embodiments, each of the compartments has space to accommodate an amount of particulate material to be coated.

According to a fourth example aspect of the invention there is provided an apparatus comprising the ALD reactor of the second example aspect and the ALD cartridge of the third aspect. The apparatus thereby forms a system. The system comprises an ALD reactor with a removable ALD reaction chamber cartridge.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The invention will now be described, by way of example only, with reference to the accompanying drawings, in which:

FIG. 1 shows a deposition reactor and method for coating particles in accordance with an example embodiment;

FIG. 2 shows flow vibrations in accordance with an example embodiment;

FIG. 3 shows a method for causing flow vibrations in accordance with an example embodiment;

FIG. 4 shows a deposition reactor and method for coating particles in accordance with an alternative embodiment;

FIGS. 5A-5D show different example embodiments to feed gases and particles into a cartridge reaction chamber;

FIG. 6 shows a production line for coating particles in accordance with an example embodiment;

FIG. 7 shows a deposition reactor and method for coating particles in accordance with yet another example embodiment;

FIG. 8 shows a rough example of a quick coupling method in accordance with an example embodiment;

FIG. 9 shows a rough example of another quick coupling method in accordance with an example embodiment;

FIG. 10 shows a deposition reactor and method for coating particles in accordance with yet another example embodiment;

FIG. 11 shows a deposition reactor and method for coating particles in accordance with yet another example embodiment; and

FIG. 12 shows a deposition reactor and method for coating particles in accordance with yet another example embodiment.

### DETAILED DESCRIPTION

In the following description, Atomic Layer Deposition (ALD) technology is used as an example. The basics of an ALD growth mechanism are known to a skilled person. As mentioned in the introductory portion of this patent application, ALD is a special chemical deposition method based on the sequential introduction of at least two reactive precursor species to at least one substrate. The substrate is located within a reaction space. The reaction space is typically heated. The basic growth mechanism of ALD relies on the bond strength differences between chemical adsorption (chemisorption) and physical adsorption (physisorption). ALD utilizes chemisorption and eliminates physisorption during the deposition process. During chemisorption a strong chemical bond is formed between atom(s) of a solid phase surface and a molecule that is arriving from the gas phase. Bonding by physisorption is much weaker because only van der Waals forces are involved. Physisorption bonds are easily broken by thermal energy when the local temperature is above the condensation temperature of the molecules.

The reaction space of an ALD reactor comprises all the typically heated surfaces that can be exposed alternately and sequentially to each of the ALD precursor used for the deposition of thin films or coatings. A basic ALD deposition cycle consists of four sequential steps: pulse A, purge A, pulse B and purge B. Pulse A typically consists of metal precursor vapor and pulse B of non-metal precursor vapor, especially nitrogen or oxygen precursor vapor. Inactive gas, such as nitrogen or argon, and a vacuum pump are used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness.

In a typical ALD process, precursor species form through chemisorption a chemical bond to reactive sites of the heated surfaces. Conditions are typically arranged in such a way that no more than a molecular monolayer of a solid material forms on the surfaces during one precursor pulse. The growth process is thus self-terminating or saturative. For example, the first precursor can include ligands that remain attached to the adsorbed species and saturate the surface, which prevents further chemisorption. Reaction space temperature is maintained above condensation temperatures and below thermal decomposition temperatures of the utilized precursors such that the precursor molecule species chemisorb on the substrate(s) essentially intact. Essentially intact means that volatile ligands may come off the precursor molecule when the precursor molecules species chemisorb on the surface. The surface becomes essentially saturated with the first type of reactive sites, i.e. adsorbed species of the first precursor molecules. This chemisorption step is typically followed by a first purge step (purge A) wherein the excess first precursor and possible reaction by-products are removed from the reaction space. Second precursor vapor is then introduced into the reaction space. Second precursor molecules typically react with the adsorbed species of the first precursor molecules, thereby forming the desired thin film material or coating. This growth terminates once the entire amount of the adsorbed first precursor has been consumed and the surface has essentially been saturated with the second type of reactive sites. The excess of second precursor vapor and possible reaction by-product vapors are then removed by a second purge step (purge B). The cycle is then repeated until the film or coating has grown to a desired thickness. Deposition cycles can also be more complex. For example, the cycles can include three or more reactant vapor pulses separated by purging steps. All these deposition cycles form a timed deposition sequence that is controlled by a logic unit or a microprocessor.

In certain example embodiments as described in the following, thin conformal coatings are provided onto the surfaces of various particulate materials. The size of the particles depends on the particular material and the particular application. Suitable particle sizes typically range from the nanometer range up to the micrometer range. A wide variety of particulate materials can be used. The composition of a base particle and that of the coating is typically selected together so that the surface characteristics of the particle are modified in a way that is desirable for a particular application. The base particles preferably have some functional group on the surface that participates in an ALD reaction sequence that creates the coating.

FIG. 1 shows a deposition reactor and method for coating particles in accordance with an example embodiment. The deposition reactor comprises a removable cartridge 110. The cartridge 110 is attached to a reactor body 121. In an embodiment, the cartridge 110 is attached to the reactor body 121 by quick coupling, for example, by twisting it into a locked position. The interface formed between the cartridge 110 and reactor body 121 is sealed by a cartridge seal 116. However, in other embodiments, the seal 116 may be omitted.

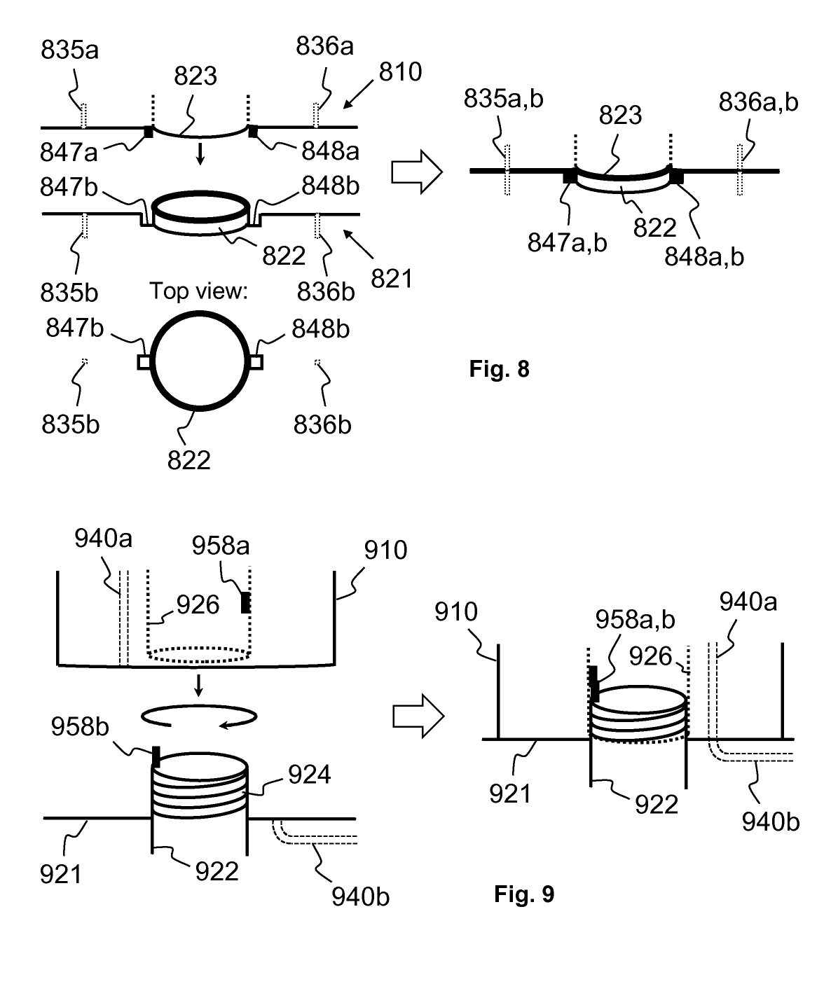

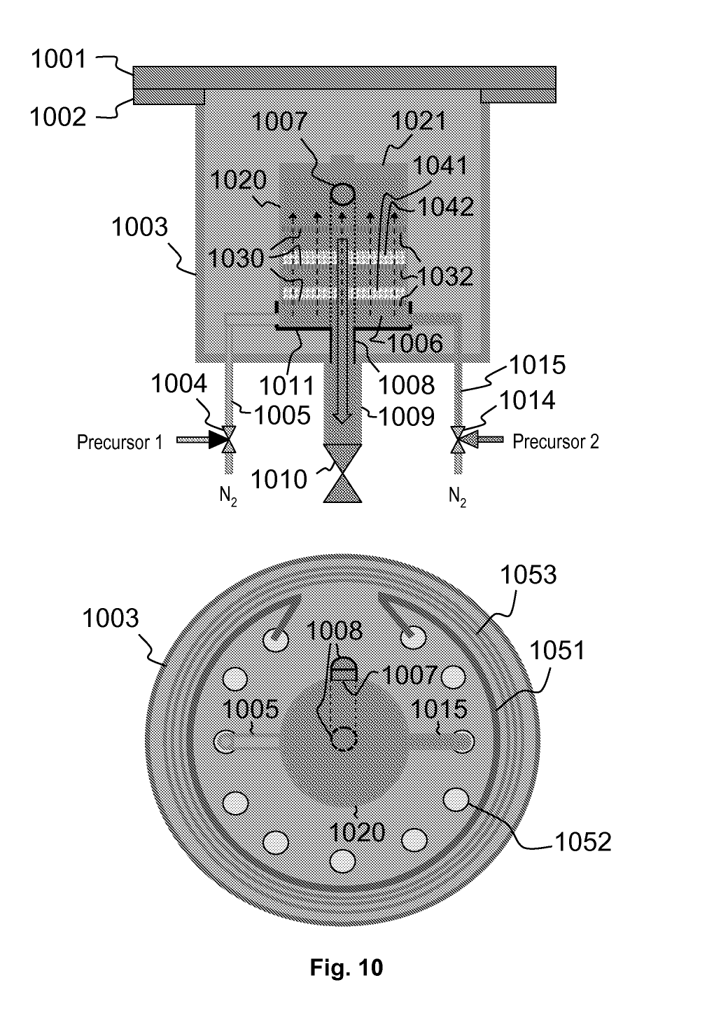

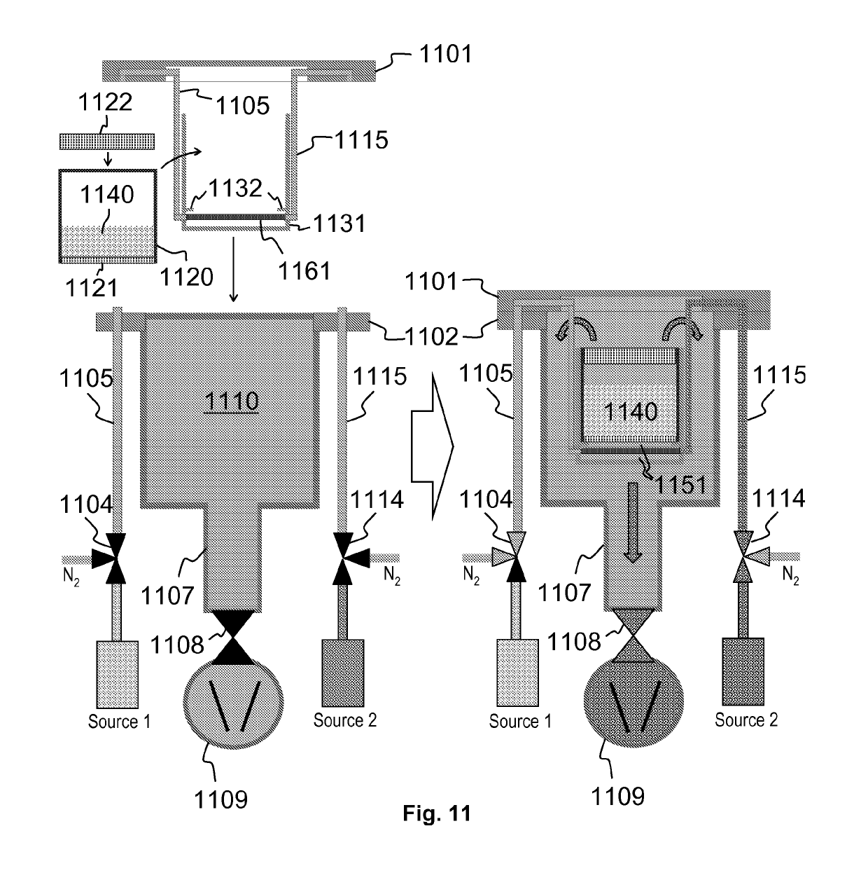

FIGS. 8 and 9 roughly show certain principles of quick coupling methods which can be applied in attaching the cartridge (here: 810, 910) into the reactor body (here: 821, 921).

The example embodiment shown in FIG. 8 shows a form locking method. The reactor body 821 comprises a receiver 822 configured to receive an attachment part 823 of the cartridge 810. The receiver 822 is formed and shaped so that depressions 847b and 848b arranged therein fit into corresponding protrusions 847a and 848a arranged into the attachment part 823 (or vice versa) locking the cartridge 810 into its correct position. In its correct position, corresponding flow conduits (835a and 835b as well as 836a and 836b in this embodiment) used in ALD processing become set in alignment with each other. The receiver 822 can be used in feeding in gases into the cartridge via the attachment part 823 from the bottom.

The example embodiment shown in FIG. 9 shows a twisting method for attaching the cartridge 910 into the reactor body 921. The reactor body 921 comprises a receiver 922 configured to receive the cartridge 910. The receiver 922 is round-shaped and comprises a thread 924 onto which the cartridge 910 can be twisted. The receiver 922 further comprises a stopping part 958b which stops the twisting movement of the cartridge 910 at a point where the stopping part 958b touches a corresponding stopping part 958a arranged in the cartridge 910 (for example in a round-shaped flow channel 926 of the cartridge 910). In this position, corresponding flow conduits 940a and 940b machined into the reactor and cartridge body parts set in alignment with each other. The conduits herein may be gas flow conduits, or conduits used in feeding particulate material into the cartridge (as shows for example in connection with FIG. 6 in the following description).

In certain example embodiments, other quick coupling methods, for example, methods containing both form locking and twisting can be used. In the preceding and other embodiments, pushing and locking methods using levers or spring-loaded levers (not shown) attached to the reactor body or to the cartridge can be used in addition or instead.

Returning to FIG. 1, the interface between the cartridge 110 and the reactor body 121 is indicated by the dotted line 152. This is also the line at which the cartridge 110 can be detached from the reactor body 121 after ALD processing.

The cartridge 110 comprises a cartridge body 112 that forms a hollow space, namely a reaction chamber 111, inside the cartridge 110. The reaction chamber 111 comprises particles to be coated, herein referred to as powder or powder particles. The cartridge 110 further comprises a top 113 which can be detached from the cartridge body 112 at line 151 for powder loading and unloading purpose. Accordingly, in an example embodiment, the cartridge 110 is loaded with powder elsewhere (pre-filled cartridge), then attached into the reactor body 121 for coating the powder particles, then detached from the reactor body 121, and then used or unloaded elsewhere, when needed.

The cartridge 110 comprises a first particle filter 114 (inlet filter 114) on the inlet side of the cartridge 110 and a second particle filter 115 (outlet filter 115) on the outlet side of the cartridge 110. The inlet filter 114 may be more coarse than the outlet filter 115 (the outlet filter 115 more fine than the inlet filter 114).

In accordance with ALD technique, precursor A via the in-feed line 131 and precursor B via the in-feed line 132 are controlled to flow alternately into the reaction chamber 111. Precursor A and B exposure periods are separated by purge steps. The gases flow into the reaction chamber 111 through a hallway 133 and the inlet filter 114. The flow causes the powder particles to whirl forming a fluidized bed 105 into the reaction chamber 111 enabling the desired coating to be grown onto the powder particles. A coating of desired thickness is obtained by repeating a required number of ALD cycles. The residual reactant molecules and reaction by-products (if any) and carrier/purge gas are controlled to flow through the outlet filter 115 via a channel 134 within the cartridge top part 113 into outlet conduits 135 and 136. The outlet conduits 135 and 136 have been arranged into the cartridge body 112 by for example machining them by a suitable method. The outlet conduits 135 and 136 continue in the reactor body part 121 in which the gases flow via channel 137 into an exhaust line.

During operation, the bottom and mid portions of the vertical reaction chamber 111 shown in FIG. 1 may be considered to form a fluidized zone in which the coating reactions occur. The upper portion of the reaction chamber 111 close the outlet filter 115 may be considered to form a disengaging zone in which the powder particles separate from the gases and drop down back to the fluidized zone.

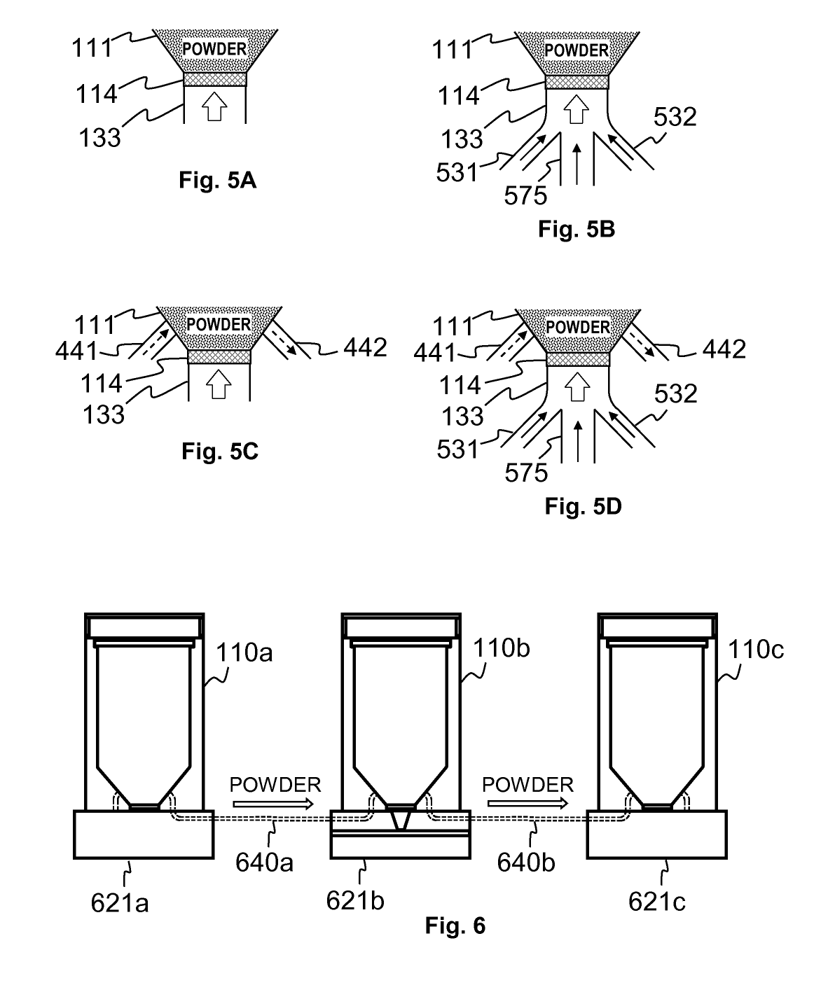

It has been observed that the powder particles in fluidized beds tend to stick to each other forming larger particle blocks, agglomerates. In order to hinder the formation of agglomerates, a vibrating gas flow is used in certain example embodiments. In these embodiments, a gas flow that vibrates is fed into the reaction chamber. Which gas flow is chosen to vibrate depends on the implementation. Certain alternatives are discussed later in this description in connection with FIGS. 5A-5D.

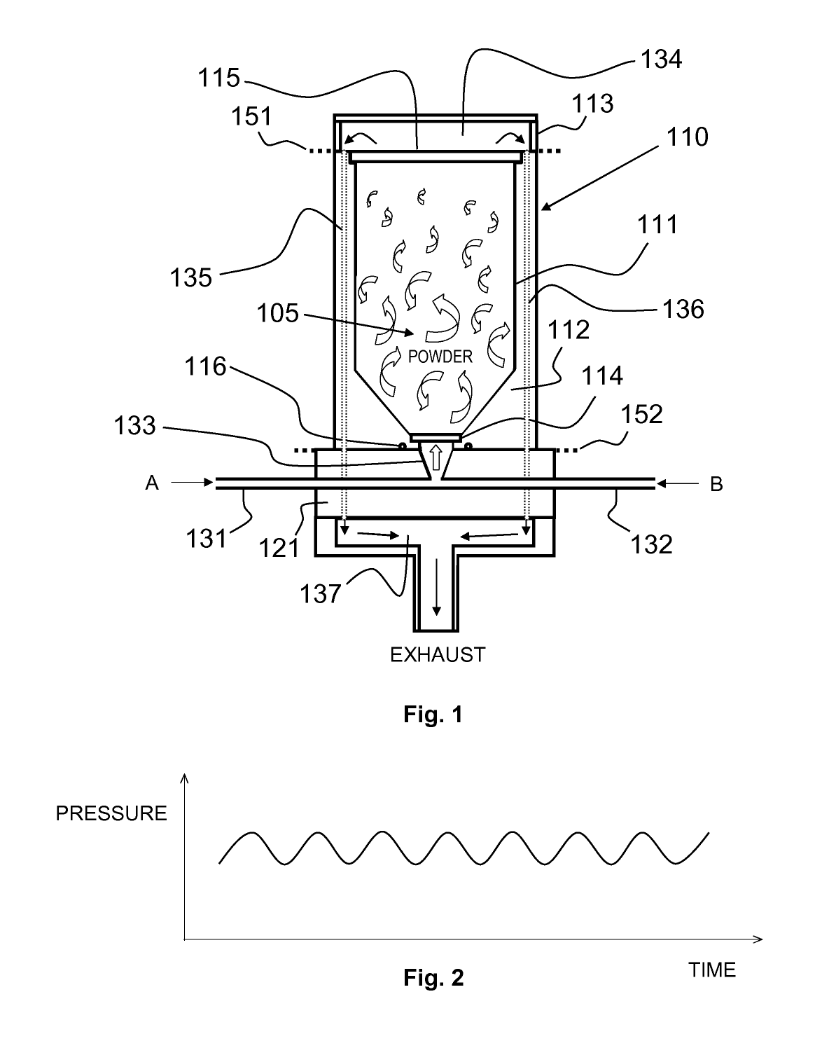

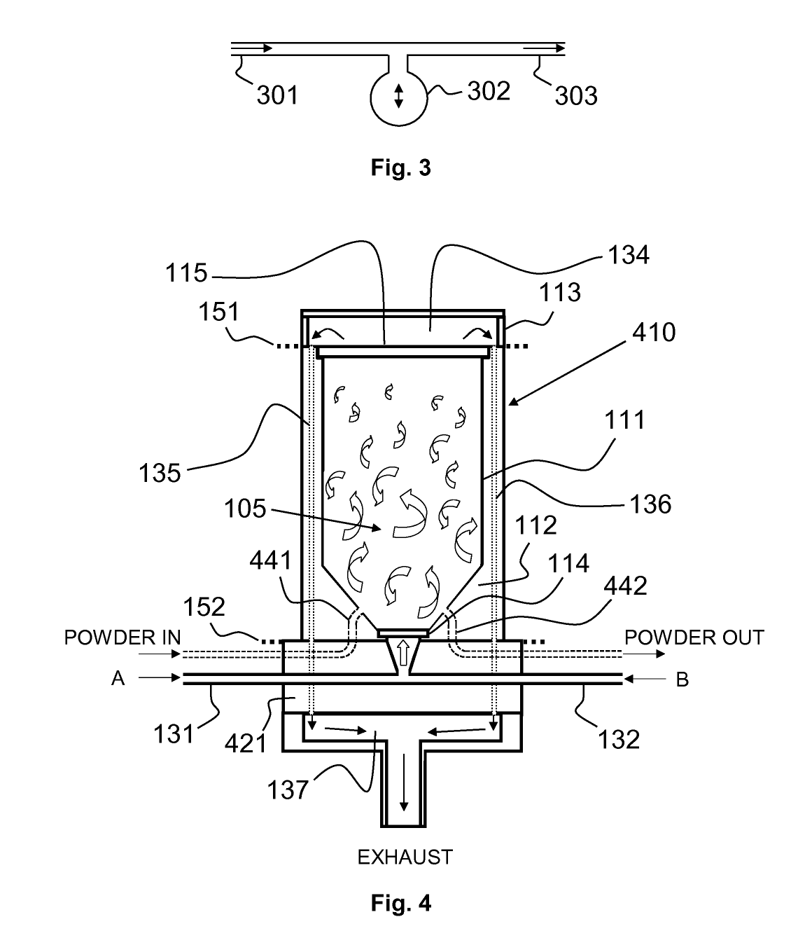

FIG. 2 shows flow vibrations in accordance with an example embodiment. The flow pressure against time is varied to cause a vibrating flow. FIG. 3 shows a method for causing flow vibrations in accordance with an example embodiment. In this method, an incoming gas flow 301 is forced over and into a cavity 302 causing vibrations into the outgoing gas flow 303. The phenomenon is based on Helmholtz resonance. The outgoing vibrating gas flow 303 is guided into the reaction chamber in order to hinder the formation of agglomerates.

FIG. 4 shows a deposition reactor and method for coating particles in accordance with an alternative embodiment. The deposition reactor shown in FIG. 4 basically corresponds to the deposition reactor shown in FIG. 1. However, there are some differences as will become evident in the following. The deposition reactor comprises a removable cartridge 410. The cartridge 410 is attached to a reactor body 421. In an embodiment, the cartridge 410 is attached to the reactor body 421 by quick coupling, for example, by twisting it into a locked position. Unlike in the example embodiment shown in FIG. 1, in the embodiment shown in FIG. 4, the cartridge seal 116 between the cartridge 410 and the reactor body 421 may be omitted, especially if the interface 152 between the cartridge 410 and the reactor body 421 is a metal against metal or a ceramic against ceramic interface or similar. Then there is much tight contact surface avoiding the need for using a separate seal. Also, when ALD processing is operated in low pressure, the need for using a separate seal reduces.

The cartridge 410 comprises a cartridge body 112 that forms a hollow space, a reaction chamber 111, inside the cartridge 410. The reaction chamber 111 comprises the powder particles to be coated. In an example embodiment, the powder particles are loaded into the reaction chamber 111 via a separate loading channel 441. The powder can be blown by an inactive gas flow through the loading channel 441 into the reaction chamber 111. In the embodiment shown in FIG. 4, the loading channel 441 has been arranged into the cartridge body 112 so that its other end is in fluid communication with (or leads to) the bottom portion of the reaction chamber 111. The loading channel 441 has been arranged into the cartridge body 112 by for example machining it by a suitable method. In the embodiment shown in FIG. 4, the loading channel 441 continues in the reactor body part 421, and the direction of the powder flow during loading is from the reactor body part 421 via the cartridge body 112 into the reaction chamber 111. The other end of the loading channel may be connected to a powder source or a loading cartridge or similar. Nitrogen, for example, can be used as the inactive gas.

After ALD processing, the coated powder particles are unloaded out of the reaction chamber 111 via an unloading channel 442. The powder can be blown by an inactive gas flow through the unloading channel 442 into a remote cartridge or container. In the embodiment shown in FIG. 4, the unloading channel 442 has been arranged into the cartridge body 112 so that its other end is in fluid communication with the bottom portion of the reaction chamber 111. The unloading channel 442 continues in the reactor body part 421, and the direction of the powder flow during unloading is from the reaction chamber 111 via the cartridge body 112 into the reactor body part 421. The other end of the unloading channel can be connected to the remote cartridge or container. The inactive gas blowing the coated powder particles can be guided into the reaction chamber 111 via the loading channel 441 so that it exits the reaction chamber via the unloading channel 442 drawing the coated powder particles with it.

The cartridge 410 for the purpose of the embodiment of FIG. 4 may be a single part cartridge or a two-part cartridge. Whilst a removable cartridge top 113 is not needed for loading and unloading, the part 113 can be useful for a cartridge cleaning purpose. In a single part cartridge embodiment, the top 113 and the rest of the cartridge 410 form a single inseparable piece.

The rest of the operational and structural features of the embodiment shown in FIG. 4 correspond to those of the embodiment shown in FIG. 1.

FIG. 5 shows different example embodiments to feed gases and powder particles into the cartridge reaction chamber 111. The example embodiment shown in FIG. 5A shows an embodiment similar to the one shown in FIG. 1. Accordingly, the precursors typically carried by carrier gas are fed into the reaction chamber 111 from the bottom through the hallway 133 and inlet filter 114. The powder particles are fed elsewhere from the top beforehand. In the embodiment where the vibrating gas flow is used, the gas flow causing vibrations during ALD processing can be the gas flow travelling along either in-feed line 131 or 132 (FIG. 1) or both. Or a separate channel for vibrating inactive gas flow can be used in addition or instead (as shown in FIGS. 5B and 5D in the following).

The example embodiment shown in FIG. 5C shows an embodiment similar to the one shown in FIG. 4. Accordingly, the precursors typically carried by carrier gas are fed into the reaction chamber 111 from the bottom through the hallway 133 and inlet filter 114. The powder particles are fed along the loading channel 441 from the bottom and unloaded along the unloading channel 442. In the embodiment where the vibrating gas flow is used, the gas flow causing vibrations during ALD processing can be the gas flow travelling along either the in-feed line 131 or 132 (FIG. 1) or both. Alternatively, or in addition, a vibrating inactive gas flow is controlled to flow during ALD processing along the loading channel 441 into the reaction chamber 111. During ALD processing there can be a small inactive gas flow towards the reaction chamber 111 in the channel 441 and/or 442 when the channel in question is not used for vibrating gas supply.

In the example embodiment shown in FIG. 5B there is a separate inlet 575 for vibrating inactive gas from the bottom, whereas precursors A and B, typically carried by carrier gas, are fed into the cartridge reaction chamber 111 via inlet 531 and 532, respectively.

In the example embodiment shown in FIG. 5D there is the separate inlet 575 for vibrating inactive gas from the bottom, but the embodiment also comprises the loading and unloading channels 441 and 442 for loading and unloading the powder particles. Alternatively, or in addition to the vibrating gas flowing via inlet 575, a vibrating inactive gas flow can be controlled to flow during ALD processing along the loading channel 441 and/or unloading channel 442 into the reaction chamber 111. During ALD processing there can be a small inactive gas flow towards the reaction chamber 111 in the channel 441 and/or 442 when the channel in question is not used for vibrating gas supply.

FIG. 6 shows an example layout for a powder coating production line. The production line comprises a triple-cartridge system. The first cartridge 110a is a loading cartridge detachably attached into a first body 621a. The powder particles to be coated are blown by inactive gas via loading channel 640a into an ALD processing cartridge 110b detachable attached into an ALD reactor body 621b. Coated powder particles are blown by inactive gas via unloading channel 640b into a third cartridge 110c detachable attached into a third body 621c. The third cartridge 110c therefore is the cartridge for the end product. Once detached from the body 621c, the third cartridge 110c can be transported to the place of use.

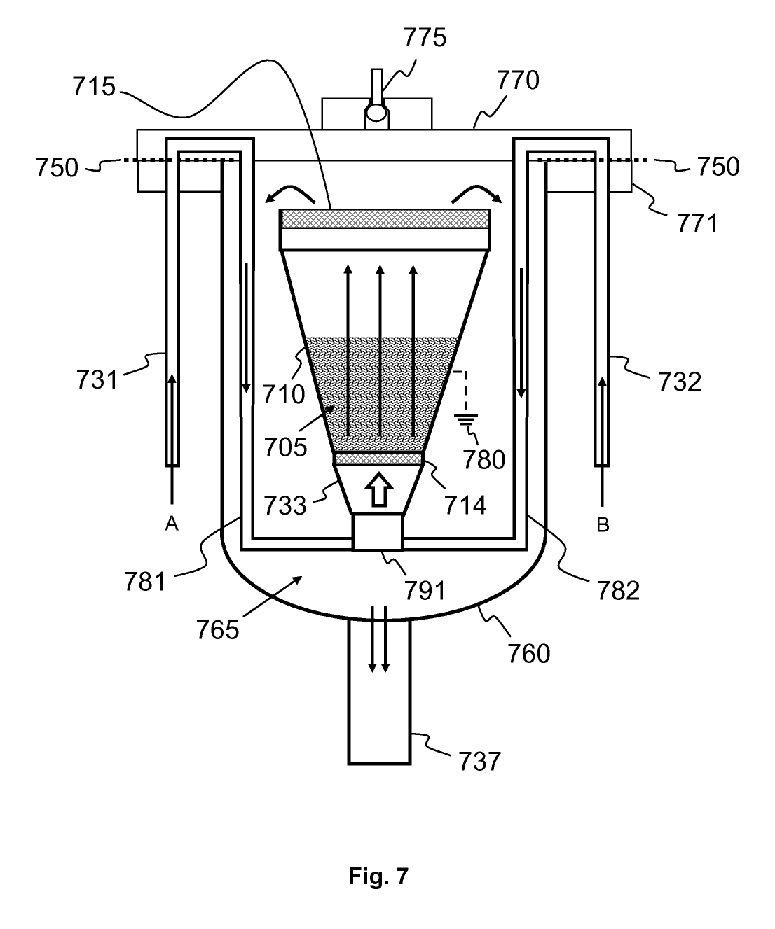

FIG. 7 shows a deposition reactor and method for coating particles in accordance with yet another example embodiment. The deposition reactor comprises a processing chamber 760 and a lid 770 which can be pressed against a processing chamber top flange 771. The processing chamber 760 houses in its reaction space 765a cartridge reaction chamber 710 filled with powder particles to be coated.

The cartridge reaction chamber 710 is coupled to the processing chamber lid 770. In the embodiment shown in FIG. 7, the cartridge reaction chamber 710 is coupled to the processing chamber lid 770 by in-feed lines 781 and 782. The cartridge reaction chamber 710 therefore can be loaded into the reaction chamber 760 by lowering the processing chamber lid 770 carrying the cartridge reaction chamber 710. The lid 770 comprises a lifting mechanism 775 with the aid of which the lid 770 can be raised and lowered. When the lid 770 is raised it raises at line 750 so that the cartridge reaction chamber 710 and pipelines 781 and 782 coupled thereto raise simultaneously.

The cartridge reaction chamber 710 is attached to processing chamber structures by quick coupling at a fitting part 791. In an example embodiment, the cartridge reaction chamber 710 can be twisted to lock into the fitting part 791 or twisted to open.

Similarly as in foregoing embodiments, the cartridge reaction chamber 710 comprises an inlet filter 714 on its bottom side and an outlet filter 715 on its top side. During ALD processing, precursor A via in-feed line 131 and precursor B via the in-feed line 132 are controlled to flow alternately into the cartridge reaction chamber 710. In the embodiment shown in FIG. 7, the in-feed lines 131 and 132 travel via the processing chamber lid 770 and have been marked by reference numerals 781 and 781 inside the processing chamber 760.

Precursor A and B exposure periods are separated by purge steps. The gases flow into the cartridge reaction chamber 710 alternately from the in-feed lines 781 and 782 through a hallway 133 and the inlet filter 714 from the bottom. The flow causes the powder particles to whirl forming a fluidized bed 705 into the cartridge reaction chamber 710 enabling the desired coating to be grown onto the powder particles. A coating of desired thickness is obtained by repeating a required number of ALD cycles. From the cartridge reaction chamber 710 the gases flow through the outlet filter 715 from the top into the reaction space 765 of the surrounding processing chamber 760 and therefrom into an exhaust line 737.

The cartridge reaction chamber 710 is connected to the ground 780 to prevent static electricity generated by the movement and collisions of powder particles from being excessively accumulated into the cartridge reaction chamber 710. The connection to the ground is also applicable in foregoing embodiments.

The vibrating gas supply into the cartridge reaction chamber 710, if implemented, can be implemented via the existing pipelines/in-feed lines.

FIG. 10 shows a deposition reactor and method for coating particles in accordance with yet another example embodiment. The deposition reactor comprises a receiver 1011 within a processing chamber 1003. The receiver 1011 is configured to receive a removable cartridge 1020 into the processing chamber 1003 by a quick coupling method, such as a form-locking method or similar.

The deposition reactor comprises a processing chamber lid 1001 which lies on a processing chamber top flange 1002 during operation. The cartridge 1020 can be loaded into the processing chamber 1003 from the top of the processing chamber 1003 when the processing chamber lid 1001 is raised aside.

The cartridge 1020 shown in this embodiment is a cylindrical reaction chamber comprising therein a plurality of filter plates 1030 set on top of each other to form a plurality of compartments therebetween, each compartment having space to accommodate an amount of particulate material to be coated. In the embodiment shown in FIG. 10 there are three filter plates and two compartments therebetween (although in other embodiments there may be less compartments, that is, only a single compartment, or more, that is three or more compartments). The filter plates 1030 lie on filter supports 1032 arranged into the sidewall of the cartridge 1020. The filter plates 1030 allow precursor vapor and inactive gas to flow therethrough, but do not allow the particulate material to go through. In practice, one or more of the filter plates 1030 may be sinter filters.

The lowest of the filter plates 1030 functions as an inlet filter. The uppermost of the filter plates 1030 functions as an outlet filter. In the embodiment shown in FIG. 10, a first compartment is formed between the lowest filter plate and the next (i.e., second) filter plate. A second compartment is formed between that (i.e., second) filter plate and the uppermost (i.e., third) filter plate. The first compartment accommodates a first amount of particulate material 1041 to be coated. The second compartment accommodates a second amount of particulate material 1042 to be coated. The particulate material in the first compartment may be the same of different particulate material compared to the particulate material in the second compartment.

The cartridge 1020 comprises a lid 1021 which closes the cartridge on the top. One or more of the filter plates 1030 and the particulate material can be loaded from the top of the cartridge 1020 when the lid 1021 is moved aside.

In the embodiment shown in FIG. 10, the cartridge 1020 further comprises in its top part an aperture 1007 in the cartridge sidewall leading to an exhaust channel 1008. The exhaust channel 1008 travels outside of the cartridge 1020 and leads into an exhaust guide 1009 of the deposition reactor. In the continuation of the exhaust guide 1009 the deposition reactor comprises an exhaust valve 1010 through which gases are pumped to a vacuum pump (not shown).

The deposition reactor further comprises in-feed lines to feed precursor vapor and/or inactive gas into the processing chamber as required by the ALD process. In FIG. 10 a first in-feed line configured to feed precursor vapor of a first precursor and/or inactive gas is denoted by reference numeral 1005, and a second in-feed line configured to feed precursor vapor of a second precursor and/or inactive gas is denoted by reference numeral 1015. In-feed of precursor vapor and inactive gas is controlled by a first in-feed valve 1004 in the first in-feed line 1005 and by a second in-feed valve 1014 in the second in-feed line 1015.

Below the inlet filter the cartridge 1020 comprises a gas spreading space 1006. In certain embodiments, the gas spreading space 1006 helps to cause a uniform bottom-to-top flow of precursor vapor within the cartridge 1020. In an alternative embodiment, the gas spreading space 1006 is formed by the deposition reactor by a suitable structure. In such an embodiment, the inlet filter may form the bottom of the cartridge 1020.

The upper drawing of FIG. 10 shows the deposition reactor in operation during the exposure period of second precursor. The mixture of precursor vapor of the second precursor and inactive gas (here: N₂) flows via the second in-feed line 1015 into the gas spreading space 1006, whilst only inactive gas flows into the gas spreading space 1006 via the first in-feed line 1005. The flow continues from the gas spreading space 1006 into the compartments causing the particulate material particles to whirl forming fluidized beds within the compartments (depending on certain factors, such as the flow rate and the weight of the particles). The gas flow exits the cartridge 1020 via the aperture 1007 into the exhaust channel 1008. Vibrating gas flow may be used similarly as presented in the foregoing.

The lower drawing of FIG. 10 together with the upper drawing of FIG. 10 shows that the route of the exhaust channel 1008 outside of the cartridge 1020 may be such that the exhaust channel 1008 first travels along the side of the cartridge 1020, and then along the center axis of the (cylindrical) cartridge 1020 below the cartridge 1020 to obtain flow symmetry.

The lower drawing of FIG. 10 also shows a processing chamber heater 1051 and heat reflectors 1053 around the cartridge 1020 within the processing chamber 1003. Furthermore, the lower drawing of FIG. 10 shows the in-feed lines 1005 and 1015 as well as the heater 1051 travelling through processing chamber feedthroughs 1052. After passing through the feedthroughs 1052 in a vertical direction, the in-feed lines 1005 and 1015 take a turn and continue in a horizontal direction into the gas spreading space 1006.

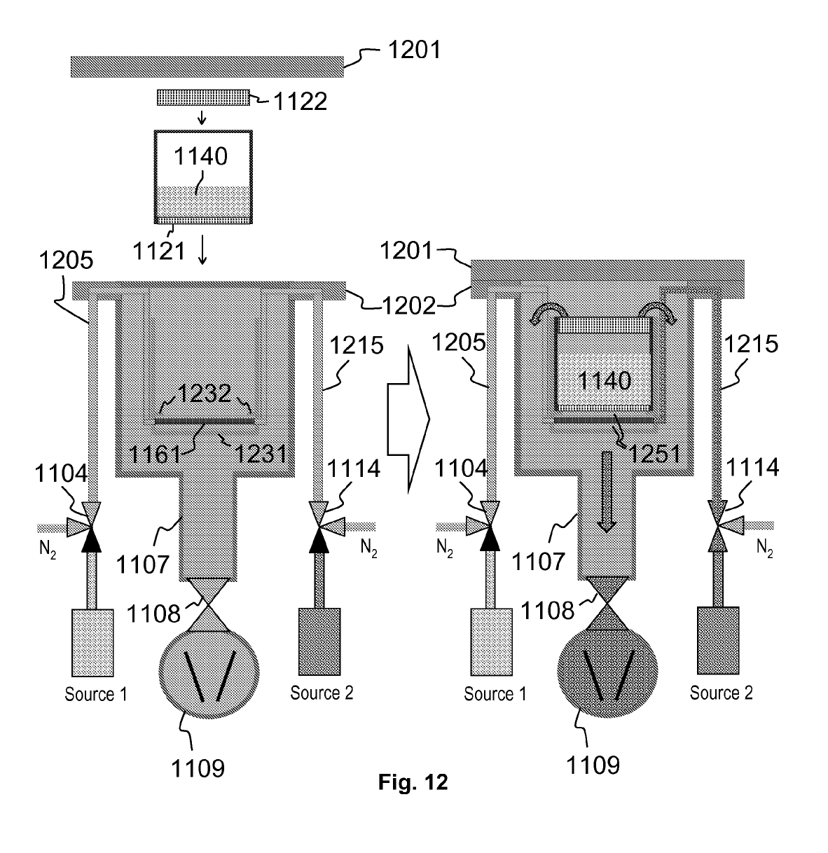

FIG. 11 shows a deposition reactor and method for coating particles in accordance with yet another example embodiment. This embodiment has certain similarities with the embodiments shown in FIG. 7 and FIG. 10 concerning which a reference is made to the description of FIG. 7 and FIG. 10.

The left-hand drawing of FIG. 11 is an assembly drawing. The right-hand drawing shows the deposition reactor in operation during the exposure period of second precursor. The deposition reactor comprises a processing chamber 1110. The processing chamber 1110 is closed by a processing chamber lid 1101 from the top. The processing chamber lid 1101 lies on a processing chamber top flange 1102 during operation.

The deposition reactor comprises a first precursor source and a second precursor source. The deposition reactor further comprises in-feed lines to feed precursor vapor and/or inactive gas into the processing chamber as required by the ALD process. In FIG. 11 a first in-feed line configured to feed precursor vapor of the first precursor and/or inactive gas is denoted by reference numeral 1105, and a second in-feed line configured to feed precursor vapor of the second precursor and/or inactive gas is denoted by reference numeral 1115. In-feed of precursor vapor and inactive gas is controlled by a first in-feed valve 1104 in the first in-feed line 1105 and by a second in-feed valve 1114 in the second in-feed line 1115.

A receiver 1131 is configured to receive a removable cartridge 1120 into the processing chamber 1110 by a quick coupling method, such as a form-locking method or similar.

The receiver 1131 is integrated to the processing chamber lid 1101. The first in-feed line 1105 goes through the processing chamber top flange 1102, takes a turn in the processing chamber lid 1101 and travels within the processing chamber lid 1101 (although in some other embodiments, the first in-feed line only travels within the processing chamber lid). Similarly, the second in-feed line 1115 goes through the processing chamber top flange 1102 on the opposite side, takes a turn in the processing chamber lid 1101 and travels within the processing chamber lid 1101 (although in some other embodiments, the second in-feed line only travels within the processing chamber lid). The first and second in-feed lines 1105 and 1115 turn downwards and travel into the receiver 1131 attaching the receiver 1131 thereby into the processing chamber lid 1101. In other words, the in-feed lines 1105 and 1115 carry the receiver 1131.

The receiver 1131 comprises supports 1132 arranged into the sidewall(s) of the receiver 1131. The cartridge 1120 when loaded into its place in the receiver 1131 is supported by the supports 1132.

The cartridge 1120 shown in this embodiment is a cylindrical reaction chamber comprising a cylindrical body (or cylindrical wall), an inlet filter 1121 at the bottom and an outlet filter 1121 on the top. The inlet filter 1121 and/or the outlet filter 1122 may be sinter filters. Alternatively, the cartridge 1120 may comprise one or more filter plates in between to form compartments within the cartridge 1120 as in the embodiment of FIG. 10. At least the outlet filter 1122 may be removable to enable loading of particulate material 1140 to be coated into the cartridge 1120.

The deposition reactor comprises and exhaust guide 1107. In the continuation of the exhaust guide 1107 the deposition reactor comprises an exhaust valve 1108 through which gases are pumped to a vacuum pump 1109.

The first in-feed line 1105 ends at a microfilter tube 1161 arranged in or in connection with the receiver 1131. Similarly, the second in-feed line 1115 ends at a microfilter tube which may be the same microfilter tube 1161 or another microfilter tube, for example a microfilter tube parallel to the microfilter tube 1161. Upon loading the cartridge 1120 its place in the receiver 1131 a confined volume 1151 around the microfilter tube(s) 1161 is formed. This confined volume is located right below the cartridge 1120 (or below its inlet filter 1121) and it functions as a gas spreading space 1151 during operation. In certain embodiments, the gas spreading space 1151 helps to cause a uniform bottom-to-top flow of precursor vapor within the cartridge 1120.

As mentioned, the right-hand drawing of FIG. 11 shows the deposition reactor in operation during the exposure period of second precursor. The mixture of precursor vapor of the second precursor and inactive gas (here: N₂) flows along the second in-feed line 1115 via the microfilter tube 1161 into the gas spreading space 1151, whilst only inactive gas flows into the gas spreading space 1151 via the first in-feed line 1105. The flow continues from the gas spreading space 1151 into the cartridge reaction chamber causing the particulate material particles to whirl forming fluidized beds within the cartridge (depending on certain factors, such as the flow rate and the weight of the particles). The gas flow exits the cartridge 1120 via the outlet filter 1122 through the top of the cartridge 1120 into the processing chamber volume 1110. From the processing chamber 1110 the gases flow into the exhaust guide 1107 at the bottom and through the exhaust valve 1108 into the vacuum pump 1109.

Vibrating gas flow may be used similarly as presented in the foregoing to hinder the formation of agglomerates within the particulate material 1140.

FIG. 12 shows a deposition reactor and method for coating particles in accordance with yet another example embodiment. The embodiment of FIG. 12 basically otherwise corresponds to the one presented in FIG. 11 except that the first and second in-feed lines 1205 and 1215 do not travel within the processing chamber lid 1201 but merely within the processing chamber top flange 1102, and the receiver 1231 in not integrated to the processing chamber lid 1101 but to the processing chamber top flange 1202.

The first in-feed line 1205 penetrates into the processing chamber top flange 1202, takes a turn and travels within the processing chamber top flange 1202. Similarly, the second in-feed line 1215 penetrates into the processing chamber top flange 1202, takes a turn and travels within the processing chamber top flange 1202. The first and second in-feed lines 1205 and 1215 turn downwards and travel into the receiver 1231 attaching the receiver 1231 thereby into the processing chamber top flange 1202. In other words, the in-feed lines 1205 and 1215 carry the receiver 1231.

A gas spreading space 1251 forms similarly as the gas spreading space 1151 in the embodiment of FIG. 11. Vibrating gas flow may be used similarly as presented in the foregoing to hinder the formation of agglomerates within the particulate material 1140.

The receiver 1231 in this embodiment, and also in certain other embodiments, is a fixed receiver integrated to the processing chamber structure, while in the embodiment of FIG. 11 the receiver 1131, although also being a fixed receiver and integrated to the processing chamber structure, was a movable receiver moving together with the processing chamber lid 1101.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended parent claims.

1. A method comprising:
receiving an atomic layer deposition (ALD) cartridge into a receiver of an ALD reactor by a quick coupling method, said ALD cartridge configured to serve as an ALD reaction chamber; and
processing surfaces of particulate material within said ALD cartridge by sequential self-saturating surface reactions.

2. The method of claim 1, wherein said quick coupling method is selected from a group consisting of: a twisting method in which the ALD cartridge is twisted until a locking member locks the ALD cartridge into its correct place, and a form locking method locking the ALD cartridge into its correct place.

3. The method of claim 1, comprising:
feeding vibrating gas into the ALD cartridge to hinder the formation of agglomerates within said particulate material.

4. The method of claim 1, comprising:
using a flow channel separate from precursor in-feed lines to feed vibrating inactive gas into the ALD cartridge during ALD processing.

5. The method of claim 1, comprising:
conducting reaction residue via at least one outlet conduit into exhaust, said at least one outlet conduit being arranged inside the ALD cartridge body.

6. The method of claim 1, comprising:
loading said particulate material via a loading channel arranged inside the ALD cartridge body.

7. The method of claim 1, comprising:
processing particulate material in a plurality of compartments arranged on top of each other, each compartment having been separated from an adjacent compartment by a filter plate.

8. An atomic layer deposition (ALD) reactor comprising:
a receiver configured to receive and ALD cartridge into the ALD reactor by a quick coupling method, said ALD cartridge configured to serve as an ALD reaction chamber; and
in-feed line(s) configured to feed precursor vapor into said ALD cartridge to process surfaces of particulate material within said ALD cartridge by sequential self-saturating surface reactions.

9. The ALD reactor of claim 8, wherein said receiver is configured to receive said ALD cartridge by a twisting method in which the ALD cartridge is twisted until a locking member locks the ALD cartridge into its correct place.

10. The ALD reactor of claim 8, wherein said receiver is configured to receive said ALD cartridge by a form locking method locking the ALD cartridge into its correct place.

11. The ALD reactor of claim 8, wherein the ALD comprises a vibration source in a flow channel configured to feed vibrating gas into the ALD cartridge to hinder the formation of agglomerates within said particulate material.

12. The ALD reactor of claim 8, comprising:
an outlet conduit inside the ALD reactor body configured to receive reaction residue from an outlet conduit arranged inside the ALD cartridge body.

13. The ALD reactor of claim 8, comprising:
a loading channel inside the ALD reactor body configured to conduct particulate material into a loading channel arranged inside the ALD cartridge body.

14. The ALD reactor of claim 8, wherein the ALD reactor is configured to form a gas spreading space before an inlet filter of the ALD cartridge.

15. A removable atomic layer deposition (ALD) cartridge configured to serve as an ALD reaction chamber and comprising a quick coupling mechanism configured to attach to an ALD reactor body of an ALD reactor by a quick coupling method, the ALD cartridge being configured to process surfaces of particulate material within said ALD cartridge by sequential self-saturating surface reactions once attached to the ALD reactor body by the quick coupling method.

16. The removable ALD cartridge of claim 15, comprising:
an outlet conduit inside the ALD cartridge body configured to conduct reaction residue via the ALD reactor body into exhaust.

17. The removable ALD cartridge of claim 15, comprising:
a plurality of filter plates on top of each other to form a plurality of particulate material coating compartments therebetween.

18. The removable ALD cartridge of claim 15, comprising:
a gas spreading space below an inlet filter.

19. An apparatus comprising the ALD reactor of any preceding claim 8-14 and the ALD cartridge of claim 15.
